(19) United States
(12) Patent Application Publication
(10) Pub. No.: US 2026/0144011 A1
(43) Pub. Date: May 21, 2026

(54) COMPOSITE COMPONENT AND MEMBER FOR SEMICONDUCTOR MANUFACTURING APPARATUS

(71) Applicant: NGK INSULATORS, LTD., Nagoya-City (JP)

(72) Inventors: Takuya YOTO, Nagakute-City (JP); Yusuke OGISO, Nagakute-City (JP)

(73) Assignee: NGK INSULATORS, LTD., Nagoya-City (JP)

(21) Appl. No.: 19/444,336

(22) Filed: Jan. 9, 2026

Related U.S. Application Data
(63) Continuation of application No. PCT/JP2025/013442, filed on Apr. 2, 2025.

(30) Foreign Application Priority Data
Jul. 18, 2024 (JP) 2024-114829

(51) Int. Cl. H10P 72/76

(52) U.S. Cl. CPC H10P 72/7616

(57) ABSTRACT

A composite component includes: a conductive member having a first plane, a second plane, and an inner-corner curved surface which is a boundary surface between the first plane and the second plane; and an insulating thermal-sprayed film that covers the first plane, the second plane, and the inner-corner curved surface. The insulating thermal-sprayed film has a planar covering portion that covers the first plane and/or the second plane and an inner-corner curved surface covering portion that covers the inner-corner curved surface. Porosity of the inner-corner curved surface covering portion and porosity of the planar covering portion are 8.0% or less, and an average distance between nearest pores having a pore diameter of 5.0 μm or more in the inner-corner curved surface covering portion and an average distance between nearest pores having a pore diameter of 5.0 μm or more in the planar covering portion are 4.0 μm or more.

### BACKGROUND OF THE INVENTION

### 1. Field of the Invention

The present invention relates to a composite component and a member for a semiconductor manufacturing apparatus.

### 2. Description of the Related Art

Conventionally, a composite component in which an insulating thermal-sprayed film is formed on a surface of a conductive member is known. For example, the composite component described in PTL 1 includes, as a conductive member, a metal support plate having a circular first surface, a second surface which is an outer peripheral surface provided so as to be adjacent to the first surface, and an outer-corner curved surface which is a boundary surface between the first surface and the second surface. The insulating thermal-sprayed film covers the first surface, the second surface, and the outer-corner curved surface. In PTL 1, an insulator is thermally sprayed onto the first surface from a direction perpendicular to the first surface while moving in a direction parallel to the first surface, an insulator is thermally sprayed onto the outer-corner curved surface from a direction perpendicular to the outer-corner curved surface while moving in a direction parallel to the outer-corner curved surface, and an insulator is thermally sprayed onto the second surface from a direction perpendicular to the second surface while moving in a direction parallel to the second surface. PTL 1 explains that the dielectric breakdown voltage (withstand voltage) of the insulating film thus obtained has become larger as compared with the conventional one.

### CITATION LIST

### Patent Literature

PTL 1: Japanese Patent No. 7422130

### SUMMARY OF THE INVENTION

However, although PTL 1 explains that the withstand voltage has increased for the insulating film formed by thermal spraying on the outer-corner curved surface, it does not mention the insulating film formed by thermal spraying on an inner-corner curved surface. The present inventors measured the withstand voltage of an insulating film formed by thermal spraying on an inner-corner curved surface and found that a sufficient withstand voltage cannot be obtained. Note that an outer corner is a mountain-fold corner portion, and an inner corner is a valley-fold corner portion.

The present invention has been made to solve such a problem, and a principal object thereof is, in a composite component in which an insulating thermal-sprayed film is formed on a surface of a conductive member, to increase the withstand voltage of both a planar covering portion of the insulating thermal-sprayed film and an inner-corner curved surface covering portion thereof.

[1]A composite component of the present invention comprises: a conductive member having a first plane, a second plane having an angle with respect to the first plane, and an inner-corner curved surface which is a boundary surface between the first plane and the second plane; and an insulating thermal-sprayed film that covers the first plane, the second plane, and the inner-corner curved surface; wherein the insulating thermal-sprayed film has: a planar covering portion that covers the first plane and/or the second plane; and an inner-corner curved surface covering portion that covers the inner-corner curved surface; wherein porosity of the inner-corner curved surface covering portion and porosity of the planar covering portion are 8.0% or less, and an average distance between nearest pores having a pore diameter of 5.0 μm or more in the inner-corner curved surface covering portion and an average distance between nearest pores having a pore diameter of 5.0 μm or more in the planar covering portion are 4.0 μm or more.

According to this composite component, the withstand voltage of both the planar covering portion and the inner-corner curved surface covering portion of the insulating thermal-sprayed film can be increased.

[2] In the composite component of the present invention (the composite component according to [1] above), it is preferable that the porosity of the inner-corner curved surface covering portion and the porosity of the planar covering portion be 4.0% or less, and it is preferable that the average distance between nearest pores having a pore diameter of 5.0 μm or more in the inner-corner curved surface covering portion and the average distance between nearest pores having a pore diameter of 5.0 μm or more in the planar covering portion be 5.8 μm or more. In this way, the withstand voltage of both the planar covering portion and the inner-corner curved surface covering portion of the insulating thermal-sprayed film can be further increased.

[3] In the composite component of the present invention (the composite component according to [1] or [2] above), it is preferable that the porosity of the planar covering portion be smaller than the porosity of the inner-corner curved surface covering portion, and it is preferable that the average distance between nearest pores having a pore diameter of 5.0 μm or more in the planar covering portion be larger than the average distance between nearest pores having a pore diameter of 5.0 μm or more in the inner-corner curved surface covering portion.

[4] In the composite component of the present invention (the composite component according to any one of [1] to [3] above), it is preferable that an average pore diameter of the inner-corner curved surface covering portion and an average pore diameter of the planar covering portion be 5.0 μm or less.

[5] In the composite component of the present invention (the composite component according to any one of [1] to [4] above), the inner-corner curved surface covering portion may have pores containing spherical splashes. It is preferable that a particle size of the splash be 3.0 μm or less.

[6]A member for a semiconductor manufacturing apparatus of the present invention comprises: a ceramic plate having a wafer placement surface on its upper surface and incorporating an electrode; and a cooling plate that is a conductive member with an insulating thermal-sprayed film, the conductive member having a circular upper surface to be bonded to a lower surface of the ceramic plate, a peripheral wall portion provided downward from a peripheral edge of the circular upper surface, and an annular surface provided radially outward from a lower end of the peripheral wall portion; wherein the cooling plate is the composite component according to any one of [1] to [5] above, the peripheral wall portion is the first plane, the annular surface is the second plane, and a boundary surface between the peripheral wall portion and the annular surface is the inner-corner curved surface.

In this member for a semiconductor manufacturing apparatus, a high voltage may be applied to the conductive member of the cooling plate to generate plasma above the wafer placement surface, but it has sufficient durability even at the time of such plasma generation.

### BRIEF DESCRIPTION OF THE DRAWINGS

FIG. 1 is a perspective view of a wafer placement table 10.

FIG. 2 is a sectional view taken along line A-A of FIG. 1.

FIG. 3 is a partially enlarged sectional view around an inner-corner curved surface covering portion 56.

FIG. 4 is a perspective view of a cooling plate 30.

FIG. 5 is a sectional view of a thermal spray gun 70.

FIG. 6 is a front view of the thermal spray gun 70.

FIG. 7 is an explanatory view illustrating forming an insulating thermal-sprayed film 50 with the thermal spray gun 70.

### DETAILED DESCRIPTION OF THE INVENTION

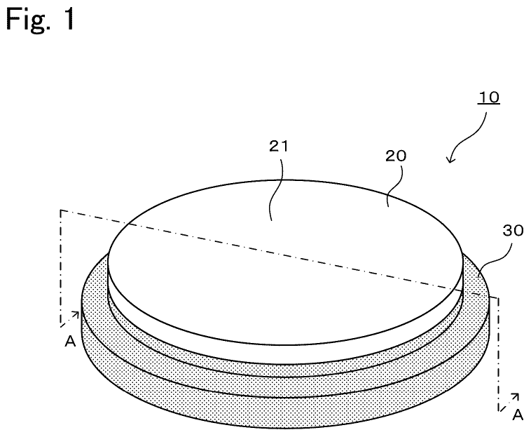

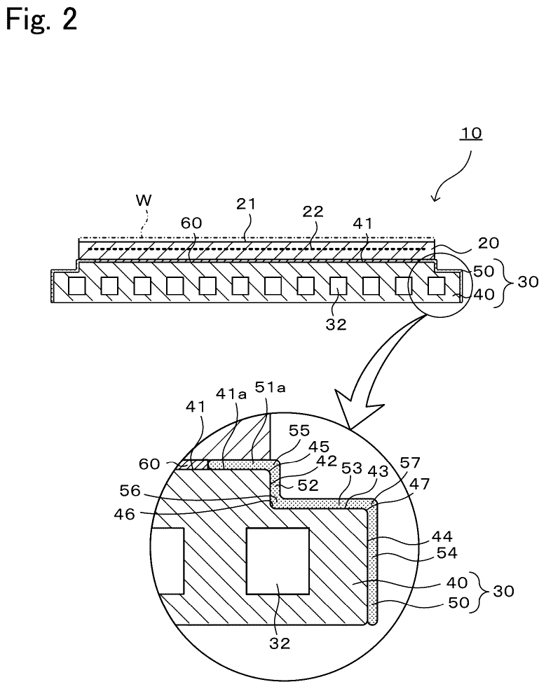

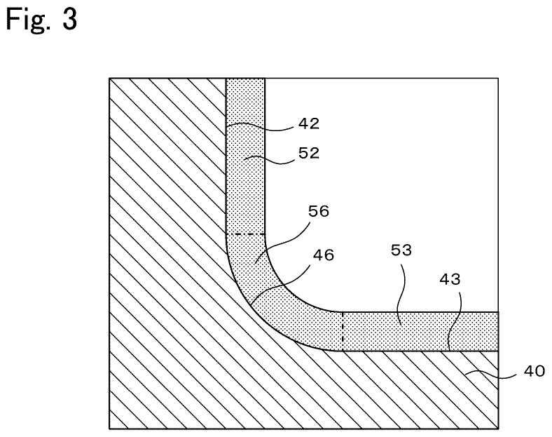

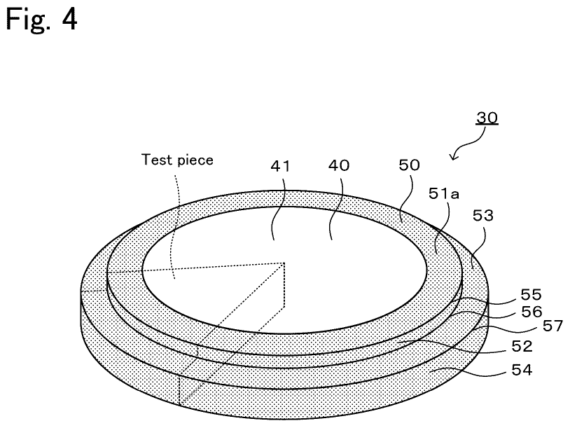

Next, preferred embodiments of the present invention will be described with reference to the drawings. FIG. 1 is a perspective view of a wafer placement table 10; FIG. 2 is a sectional view taken along line A-A of FIG. 1 (with a partially enlarged view); FIG. 3 is a partially enlarged sectional view around the inner-corner curved surface covering portion 56; and FIG. 4 is a perspective view of the cooling plate 30. The hatched portions in FIGS. 1 and 4 indicate the insulating thermal-sprayed film 50.

In this specification, “upper” and “lower” do not represent absolute positional relationships but represent relative positional relationships. Therefore, depending on the orientation of the wafer placement table 10, “upper” and “lower” may become “lower” and “upper,” or “left” and “right,” or “front” and “rear.”

As shown in FIG. 2, the wafer placement table 10 includes a ceramic plate 20, a cooling plate 30, and a bonding layer 60. The cooling plate 30 is an example of the composite component of the present invention, and the wafer placement table 10 is an example of the member for a semiconductor manufacturing apparatus of the present invention.

The ceramic plate 20 is a ceramic disk such as an alumina sintered body or an aluminum nitride sintered body (for example, diameter 300 mm, thickness 5 mm). An upper surface of the ceramic plate 20 serves as a wafer placement surface 21 on which a wafer W is placed. The ceramic plate 20 incorporates an electrode 22. The electrode 22 is a planar mesh electrode used as an electrostatic electrode and is connected to an external DC power supply via a power-feeding member (not shown). When a DC voltage is applied to this electrode 22, the wafer W is attracted and fixed to the wafer placement surface 21 by electrostatic attraction, and when application of the DC voltage is released, attraction/fixation of the wafer W to the wafer placement surface 21 is released.

The cooling plate 30 is obtained by providing an insulating thermal-sprayed film 50 on a substantially disk-shaped conductive plate 40 (an example of a conductive member).

The conductive plate 40 is a disk with steps having good thermal conductivity (a disk having the same diameter as, or a larger diameter than, the ceramic plate 20). Inside the conductive plate 40, a refrigerant flow path 32 in which a refrigerant circulates is formed. The refrigerant flow path 32 is formed, in plan view, over the entirety of the conductive plate 40 from one end (inlet) to the other end (outlet) in a one-stroke pattern. A supply port and a collection port of an external refrigerant device (not shown) are respectively connected to the one end and the other end of the refrigerant flow path 32. A refrigerant supplied to the one end of the refrigerant flow path 32 from the supply port of the external refrigerant device passes through the refrigerant flow path 32 and then returns from the other end of the refrigerant flow path 32 to the collection port of the external refrigerant device, and after temperature adjustment, is supplied again from the supply port to the one end of the refrigerant flow path 32. The conductive plate 40 is connected to a high-frequency (RF) power supply and is also used as an RF electrode.

Examples of materials for the conductive plate 40 include, for example, metal materials and composite materials of metal and ceramic. Examples of the metal materials include Al, Ti, Mo, or alloys thereof. Examples of the composite materials of metal and ceramic include metal matrix composite materials (MMCs) and ceramic matrix composite materials (CMCs). Specific examples of such composite materials include a material containing Si, SiC, and Ti (also referred to as SiSiCTi), a material obtained by impregnating a porous SiC body with Al and/or Si, and a composite material of Al₂O₃ and TiC. It is preferable to select, as a material for the conductive plate 40, a material having a coefficient of thermal expansion close to that of the material of the ceramic plate 20.

The conductive plate 40 has: a circular upper surface 41 to be bonded to a lower surface of the ceramic plate 20; an upper peripheral wall surface 42 (an example of the first plane) provided downward from a peripheral edge of the circular upper surface 41; an annular surface 43 (an example of the second plane) provided radially outward from a lower end of the upper peripheral wall surface 42; and a lower peripheral wall surface 44 provided downward from a peripheral edge of the annular surface 43. The circular upper surface 41, the upper peripheral wall surface 42, the annular surface 43, and the lower peripheral wall surface 44 are planes. Although the upper peripheral wall surface 42 and the lower peripheral wall surface 44 are each a side surface of a cylinder, they are referred to as planes for convenience. At a boundary between the circular upper surface 41 and the upper peripheral wall surface 42, an R-shaped (rounded) upper outer-corner curved surface 45 is provided; at a boundary between the upper peripheral wall surface 42 and the annular surface 43, an R-shaped inner-corner curved surface 46 is provided; and at a boundary between the annular surface 43 and the lower peripheral wall surface 44, an R-shaped lower outer-corner curved surface 47 is provided. An angle formed by the annular surface 43 and the upper peripheral wall surface 42 is 90°. However, this angle is not limited to 90° and may be, for example, 1000 or 120°. The R-shape is a rounded shape and is, for example, a curved surface having a predetermined radius of curvature. The predetermined radius of curvature is, for example, 0.3-5 mm.

The insulating thermal-sprayed film 50 covers the outer peripheral portion 41a of the circular upper surface 41, the upper outer-corner curved surface 45, the upper peripheral wall surface 42, the inner-corner curved surface 46, the annular surface 43, the lower outer-corner curved surface 47, and the lower peripheral wall surface 44. Of the insulating thermal-sprayed film 50, a portion covering the outer peripheral portion 41a of the circular upper surface 41 is referred to as a circular-upper-surface covering portion 51a; a portion covering the upper outer-corner curved surface 45 is referred to as an upper outer-corner curved surface covering portion 55; a portion covering the upper peripheral wall surface 42 is referred to as an upper-peripheral-wall-surface covering portion 52; a portion covering the inner-corner curved surface 46 is referred to as an inner-corner curved surface covering portion 56; a portion covering the annular surface 43 is referred to as an annular-surface covering portion 53; a portion covering the lower outer-corner curved surface 47 is referred to as a lower outer-corner curved surface covering portion 57; and a portion covering the lower peripheral wall surface 44 is referred to as a lower-peripheral-wall-surface covering portion 54. The circular-upper-surface covering portion 51a, the upper-peripheral-wall-surface covering portion 52, the annular-surface covering portion 53, and the lower-peripheral-wall-surface covering portion 54 are planar covering portions. Therefore, these may be collectively referred to as planar covering portions 51a, 52, 53, and 54. The upper outer-corner curved surface covering portion 55 and the lower outer-corner curved surface covering portion 57 are outer-corner curved surface covering portions. Therefore, these may be collectively referred to as outer-corner curved surface covering portions 55 and 57. Examples of materials for the insulating thermal-sprayed film 50 include metal oxides such as alumina and yttria.

In the present embodiment, regarding the planar covering portions 51a, 52, 53, and 54, the outer-corner curved surface covering portions 55 and 57, and the inner-corner curved surface covering portion 56, the porosity is 8.0% or less in all cases, and an average distance between nearest pores having a pore diameter of 5.0 μm or more is 4.0 μm or more in all cases. Thereby, the withstand voltage of the insulating thermal-sprayed film 50 becomes a high value (for example, 5.0 kV or more) regardless of the location. It is more preferable that the porosity of these be 4.0% or less, and more preferable that the average distance between nearest pores having a pore diameter of 5.0 μm or more be 5.8 μm or more in all cases. In this way, the withstand voltage of the insulating thermal-sprayed film 50 becomes a higher value.

The porosity of the planar covering portions 51a, 52, 53, and 54 and the porosity of the outer-corner curved surface covering portions 55 and 57 may be smaller than the porosity of the inner-corner curved surface covering portion 56. The average distance between nearest pores having a pore diameter of 5.0 μm or more in the planar covering portions 51a, 52, 53, and 54 and the average distance between nearest pores having a pore diameter of 5.0 μm or more in the outer-corner curved surface covering portions 55 and 57 may be larger than the average distance between nearest pores having a pore diameter of 5.0 μm or more in the inner-corner curved surface covering portion 56.

It is preferable that average pore diameters of the planar covering portions 51a, 52, 53, and 54, the outer-corner curved surface covering portions 55 and 57, and the inner-corner curved surface covering portion 56 be 5.0 μm or less. It is preferable that the inner-corner curved surface covering portion 56 have pores that contain spherical splashes. At the time of thermal spraying, powder of a thermal-spraying material hits the surface of the conductive plate 40 and is flattened and its surroundings scatter; the scattered ones are called “splash,” and the remaining ones are called “splat.” It is preferable that a particle diameter of the spherical splash be 3.0 μm or less.

The bonding layer 60 bonds a lower surface of the ceramic plate 20 and an upper surface (the circular upper surface 41 of the conductive plate 40) of the cooling plate 30. The bonding layer 60 may be a resin layer or may be a metal layer. The resin layer may be formed, for example, with a silicone resin adhesive, or may be formed with an acrylic resin adhesive, or may be formed with a bonding sheet. Examples of the bonding sheet include a sheet having acrylic resin layers on both sides of a polypropylene core, a sheet having silicone resin layers on both sides of a polyimide core, and a sheet of epoxy resin alone. The metal layer may be a layer formed by TCB (thermal compression bonding), for example, or may be a layer formed of solder or a brazing filler metal.

Next, an example of use of the wafer placement table 10 thus constructed will be described. First, with the wafer placement table 10 installed in an chamber (not shown), the wafer W is placed on the wafer placement surface 21. The inside of the chamber is depressurized by a vacuum pump to be adjusted to a predetermined degree of vacuum, a DC voltage is applied to the electrode 22 of the ceramic plate 20 to generate electrostatic attraction, and the wafer W is attracted and fixed to the wafer placement surface 21. Next, a reaction gas atmosphere at a predetermined pressure (for example, several tens to several hundreds of Pa) is established in the chamber, and plasma is generated by applying a high-frequency voltage between an upper electrode (not shown) provided on a ceiling portion in the chamber and the conductive plate 40. The surface of the wafer W is processed by the generated plasma. A refrigerant is circulated in the refrigerant flow path 32 of the cooling plate 30.

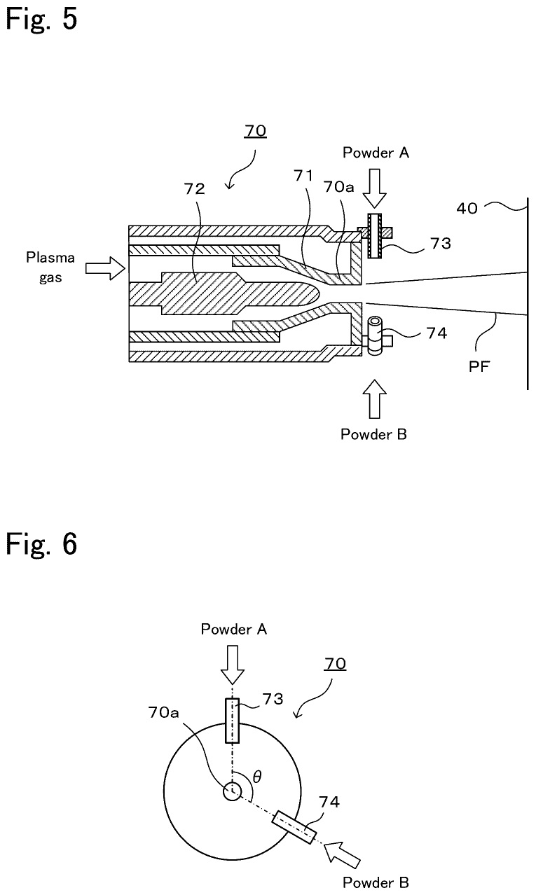

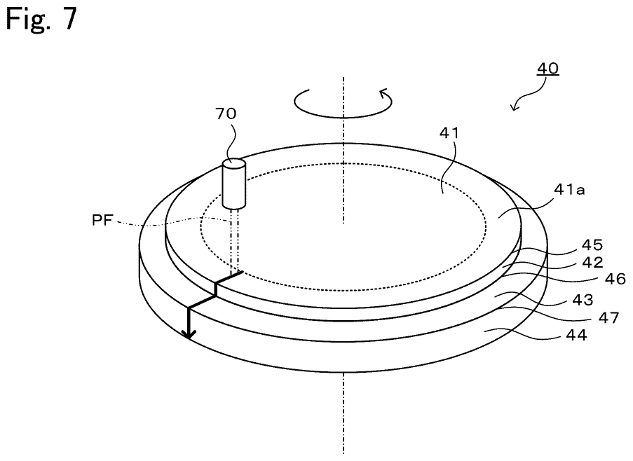

Next, a method of manufacturing the wafer placement table 10 will be described. Since the ceramic plate 20 and the conductive plate 40 can be manufactured by known methods, a method of forming the insulating thermal-sprayed film 50 on the conductive plate 40 (thermal-sprayed film forming method) will be described here. FIG. 5 is a sectional view of a thermal spray gun 70, FIG. 6 is a front view of the thermal spray gun 70, and FIG. 7 is an explanatory view showing a process of forming the insulating thermal-sprayed film 50. Note that a front face of the thermal spray gun 70 is a face on which a nozzle 70a opens.

The insulating thermal-sprayed film 50 is formed on a surface of the conductive plate 40 (the outer peripheral portion 41a of the circular upper surface 41, the upper outer-corner curved surface 45, the upper peripheral wall surface 42, the inner-corner curved surface 46, the annular surface 43, the lower outer-corner curved surface 47, and the lower peripheral wall surface 44) by atmospheric plasma spraying using the thermal spray gun 70.

In atmospheric plasma spraying, first, a DC voltage is applied between an anode 71 and an opposing cathode 72 which constitute the nozzle 70a of the thermal spray gun 70 so as to generate an arc between both electrodes. At the same time, a plasma gas (such as Ar gas) is supplied to the nozzle 70a. Thereby, a plasma flame PF is emitted from the nozzle 70a. Next, a powder A is supplied from a first port 73 and a powder B is supplied from a second port 74 into the plasma flame PF. When an average particle diameter D50 of the powder A is a [μm] and an average particle diameter D50 of the powder B is b [μm], a is smaller than b. It is preferable that a and b satisfy 1.5≤b/a≤2.5, and more preferable that they satisfy 1.8≤b/a≤2.2. It is preferable that a be 5-40, and it is preferable that b be 10-80. It is more preferable that a be 5-30, and more preferable that b be 10-60. As materials of the powders A and B, metal oxides such as alumina and yttria can be exemplified. The powders A and B supplied into the plasma flame PF are melted or brought into a state close to melting by being accelerated in a high-temperature state and are deposited on the surface of the conductive plate 40. Thus, the insulating thermal-sprayed film 50 is formed on the surface of the conductive plate 40. A method of carrying out atmospheric plasma spraying by supplying a small-particle powder A from one port (the first port 73) and a large-particle powder B from another port (the second port 74) is referred to as a two-port spraying method.

As shown in FIG. 6, the first port 73 and the second port 74 are arranged such that an angle θ formed by an axis of the first port 73 and an axis of the second port 74 with the nozzle 70a as a center becomes a predetermined angle. The angle θ is set in a range of 0-180°, and is preferably set in a range of 30-150°.

In the present embodiment, as shown in FIG. 7, with the conductive plate 40 in a state of axial rotation, the thermal spray gun 70 is moved along a bold-line arrow (radial direction). At this time, while moving, an attitude of the thermal spray gun 70 is controlled such that an axis of the nozzle 70a (the plasma flame PF) is not perpendicular to, but has an angle relative to, the surface of the conductive plate 40 (the outer peripheral portion 41a of the circular upper surface 41, the upper outer-corner curved surface 45, the upper peripheral wall surface 42, the inner-corner curved surface 46, the annular surface 43, the lower outer-corner curved surface 47, and the lower peripheral wall surface 44). For example, an angle of the axis of the nozzle 70a with respect to a normal direction of the surface of the conductive plate 40 may be set in a range of 1-50°.

The formed insulating thermal-sprayed film 50 has: the circular-upper-surface covering portion 51a, the upper-peripheral-wall-surface covering portion 52, the annular-surface covering portion 53, and the lower-peripheral-wall-surface covering portion 54 which are planar covering portions; the upper outer-corner curved surface covering portion 55 and the lower outer-corner curved surface covering portion 57 which are outer-corner curved surface covering portions; and the inner-corner curved surface covering portion 56. The planar covering portions 51a, 52, 53, and 54, the outer-corner curved surface covering portions 55 and 57, and the inner-corner curved surface covering portion 56 all satisfy the above-described characteristics (porosity and average distance between nearest pores having a pore diameter of 5.0 μm or more, etc.).

In the cooling plate 30 of the wafer placement table 10 described above in detail, regarding the planar covering portions 51a, 52, 53, and 54, the outer-corner curved surface covering portions 55 and 57, and the inner-corner curved surface covering portion 56, the porosity is 8.0% or less in all cases, and the average distance between nearest pores having a pore diameter of 5.0 μm or more is 4.0 μm or more in all cases. Therefore, the withstand voltage of the insulating thermal-sprayed film 50 becomes a high value regardless of the location. Further, if the porosity of these is 4.0% or less in all cases and the average distance between nearest pores having a pore diameter of 5.0 μm or more is 5.8 μm or more in all cases, the withstand voltage of the insulating thermal-sprayed film 50 becomes a higher value.

Also, the porosity of the planar covering portions 51a, 52, 53, and 54 and the porosity of the outer-corner curved surface covering portions 55 and 57 may be smaller than the porosity of the inner-corner curved surface covering portion 56. The average distance between nearest pores having a pore diameter of 5.0 μm or more in the planar covering portions 51a, 52, 53, and 54 and the average distance between nearest pores having a pore diameter of 5.0 μm or more in the outer-corner curved surface covering portions 55 and 57 may be larger than the average distance between nearest pores having a pore diameter of 5.0 μm or more in the inner-corner curved surface covering portion 56.

Further, it is preferable that the average pore diameters of the planar covering portions 51a, 52, 53, and 54, the outer-corner curved surface covering portions 55 and 57, and the inner-corner curved surface covering portion 56 be 5.0 μm or less. It is preferable that the inner-corner curved surface covering portion 56 have pores that contain spherical splashes.

It goes without saying that the present invention is not limited to the above-described embodiment and can be implemented in various modes within the technical scope of the present invention.

In the above-described embodiment, an example of implementing the two-port spraying method using the thermal spray gun 70 provided with two ports has been shown, but the invention is not limited thereto. For example, a thermal spray gun provided with three or more ports may be used. When a thermal spray gun provided with three or more ports is used, all of those ports may be used, or two or more of those ports may be used, not all. In any case, if two kinds of powders having different average particle diameters are supplied from at least two ports to the plasma flame, the two-port spraying method can be implemented.

In the above-described embodiment, the two-port spraying method has been exemplified, but the composite component of the present invention is not limited to one manufactured by the two-port spraying method. For example, using a thermal spray gun provided with three or more ports, an insulating thermal-sprayed film 50 may be formed on the surface of the conductive plate 40 by supplying at least three kinds of powders having different average particle diameters from three or more of those ports. In this case, when an average particle diameter D50 of a smallest powder among the at least three kinds of powders having different average particle diameters is set as a [μm] and an average particle diameter D50 of a largest powder is set as b [μm], it is preferable to satisfy 1.5≤b/a≤2.5.

In the above-described embodiment, the cooling plate 30 has been exemplified as the composite component of the present invention, but it is not limited particularly to the cooling plate 30.

In the above-described embodiment, the ceramic plate 20 has been exemplified as incorporating an electrostatic electrode as the electrode 22, but the ceramic plate 20 may incorporate, as the electrode 22, in place of or in addition to the electrostatic electrode, a heater electrode (resistance heating element) and/or an RF electrode (plasma-generating electrode).

In the above-described embodiment, the insulating thermal-sprayed film 50 has been provided on a part (the outer peripheral portion 41a) of the circular upper surface 41 of the conductive plate 40, but the insulating thermal-sprayed film 50 may be provided over the entire surface of the circular upper surface 41.

### EXAMPLES

### Experimental Examples 1-9

In Experimental Examples 1-6, an insulating thermal-sprayed film 50 was formed on an aluminum conductive plate 40 by the two-port spraying method described in the above embodiment, and a cooling plate 30 was manufactured. As the powder used, an alumina powder was used. Specific conditions of the two-port spraying method in Experimental Examples 1-6 are shown in Table 1.

In Experimental Examples 7-9, instead of the two-port spraying method, a cooling plate was manufactured by forming an insulating thermal-sprayed film on the conductive plate 40 by a one-port spraying method (a method of carrying out atmospheric plasma spraying by supplying a powder having a predetermined average particle diameter only from the first port 73 of the thermal spray gun 70). Specific conditions of the one-port spraying method in Experimental Examples 7-9 are shown in Table 1.

In Table 1, “2 ports (120° interval)” indicates that an angle θ (see FIG. 6) formed by an axis of the first port 73 and an axis of the second port 74 is 120°. “Current” is a current flowing between both electrodes 71 and 72 of the thermal spray gun 70 when generating an arc. “Spray distance” is a distance from a tip of the nozzle 70a of the thermal spray gun 70 to the surface of the conductive plate 40.

TABLE 1

| | | | Powder | | Plasma gas | Spray |
|---|---|---|---|---|---|---|
| Experimental | Spraying | Powder | used | Current | flow rate | distance |
| Example | method | supply | D50[μm] | [A] | [L/min] | [mm] |
| 1 | Atmospheric | 2 ports | a = 15 | 450 | 190 | 150 |
| | plasma spraying | (120° interval) | b = 30 | | | |
| 2 | Atmospheric | 2 ports | a = 15 | 450 | 180 | 150 |
| | plasma spraying | (120° interval) | b = 30 | | | |
| 3 | Atmospheric | 2 ports | a = 15 | 450 | 160 | 150 |
| | plasma spraying | (120° interval) | b = 30 | | | |
| 4 | Atmospheric | 2 ports | a = 15 | 450 | 150 | 150 |
| | plasma spraying | (120° interval) | b = 30 | | | |
| 5 | Atmospheric | 2 ports | a = 15 | 450 | 130 | 150 |
| | plasma spraying | (120° interval) | b = 30 | | | |
| 6 | Atmospheric | 2 ports | a = 15 | 450 | 140 | 150 |
| | plasma spraying | (120° interval) | b = 30 | | | |
| 7 | Atmospheric | 1 port | 30 | 420 | 100 | 150 |
| | plasma spraying | | | | | |
| 8 | Atmospheric | 1 port | 15 | 450 | 190 | 150 |
| | plasma spraying | | | | | |
| 9 | Atmospheric | 1 port | 25 | 420 | 100 | 150 |
| | plasma spraying | | | | | |

### Characteristics

### Test Piece

From the cooling plates 30 of Experimental Examples 1-6, test pieces were cut out and various characteristics (average distance between nearest pores having a pore diameter of 5.0 μm or more, porosity, average pore diameter, presence/absence of splash, and withstand voltage) were measured. The test piece was one cut out from the cooling plate 30 so as to be a sector with a central angle of about 30° when the cooling plate 30 is viewed in plan (see a dotted line in FIG. 4). A polished surface for evaluation tests was one obtained by finishing a cut surface of the test piece into a mirror surface by polishing. The polishing was performed in the order of 3 μm diamond abrasive grains and 0.5 μm diamond abrasive grains, and final finishing was performed by lap polishing using diamond abrasive grains of 0.1 μm or less. For Experimental Examples 7-9 as well, test pieces were cut out in the same manner as in Experimental Examples 1-6, and various characteristics were measured. Methods of measuring various characteristics are described below. Measurement results are shown in Table 2. Note that “inner-corner portion” refers to the inner-corner curved surface covering portion 56, and “planar portion” refers to the annular-surface covering portion 53.

### Average Distance Between Nearest Pores Having a Pore Diameter of 5.0 μm or More

For the inner-corner portion, a polished surface for evaluation tests was observed by SEM at a magnification of 100×, and for each pore having a circumscribed-circle diameter of 5.0 μm or more present per 450 μm×450 μm, a distance to another pore having a circumscribed-circle diameter of 5.0 μm or more was measured, the smallest distance among them was taken as a nearest-pore distance for pores having a pore diameter of 5.0 μm or more, an average value of all the nearest-pore distances having a pore diameter of 5.0 μm or more was calculated, and this was taken as the average distance between nearest pores having a pore diameter of 5.0 μm or more. For the planar portion, the average distance between nearest pores having a pore diameter of 5.0 μm or more was obtained in the same manner as for the inner-corner portion except that a region in the above-described SEM observation was 1200 μm×400 μm. However, as a premise of image processing, for noise suppression, extremely small pores (pores having an area of less than 2.5 μm²) were excluded. This point was the same for the porosity and the average pore diameter below.

### Porosity

For the porosity of the inner-corner portion, in the above-described SEM observation, a total area of pores present per 450 μm×450 μm was measured and calculated based on the area ratio. For the porosity of the planar portion, in the above-described SEM observation, a total area of pores present per 1200 μm×400 μm was measured and calculated based on the area ratio.

### Average Pore Diameter

For the average pore diameter of the inner-corner portion, in the above-described SEM observation, a number of pores and a maximum length of the pores present per 450 μm×450 μm were measured, and an average value of the maximum lengths of the pores was taken as the average pore diameter. For the average pore diameter of the planar portion, in the above-described SEM observation, a number of pores and a maximum length of the pores present per 1200 μm×400 μm were measured, and an average value of the maximum lengths of the pores was taken as the average pore diameter.

### Presence/Absence of Splash

For the inner-corner portion, in the above-described SEM observation, it was confirmed whether a splash (a sphere having a diameter of 3.0 μm or more) was present in pores present per 450 μm×450 μm. For the planar portion, in the above-described SEM observation, it was confirmed whether a splash (a sphere having a diameter of 3.0 μm or more) was present in pores present per 1200 μm×400 μm.

### Withstand Voltage

The test piece was placed on an aluminum electrode plate, a measurement position of the test piece was pressed from above with a jig provided with a weight (550 g), a DC voltage was applied between the electrode plate and the jig, and a dielectric breakdown voltage (withstand voltage) was measured. The measurement positions were three positions (left, center, right) in the inner-corner portion and also three positions (left, center, right) in the planar portion. The withstand voltage was an average value of the three measured positions. A test piece having a withstand voltage of 5.0 kV or more was judged to be a good product.

TABLE 2

| | Inner-corner portion*¹ | | | | Planar portion*¹ | | | |
|---|---|---|---|---|---|---|---|---|
| | Average distance | Average | | | Average distance | Average | | |
| | between nearest | pore | | Withstand | between nearest | pore | | Withstand |
| Experimental | pores | diameter | Porosity | voltage | pores | diameter | Porosity | voltage |
| Example*² | [μm] | [μm] | [%] | [kV] | [μm] | [μm] | [%] | [kV] |
| 1 | 10.9 | 4.4 | 1.8 | 7.3 | 20.6 | 4.0 | 1.0 | 7.5 |
| 2 | 10.7 | 4.4 | 1.8 | 7.1 | 28.3 | 3.9 | 0.65 | 10.0 |
| 3 | 8.9 | 4.2 | 2.4 | 6.0 | 27.0 | 3.9 | 0.62 | 9.3 |
| 4 | 5.8 | 4.5 | 3.6 | 7.0 | 23.5 | 3.9 | 0.78 | 7.8 |
| 5 | 4.8 | 5.0 | 8.0 | 5.1 | 6.8 | 5.0 | 1.5 | 6.0 |
| 6 | 4.1 | 4.8 | 5.8 | 5.1 | 15.2 | 4.2 | 1.2 | 6.2 |
| 7 | 3.7 | 7.0 | 11.8 | 2.2 | 5.0 | 6.3 | 3.8 | 6.3 |
| 8 | 3.6 | 7.8 | 8.6 | 4.6 | 15.1 | 5.1 | 1.1 | 7.1 |
| 9 | 3.5 | 6.1 | 8.4 | 4.1 | 4.7 | 5.7 | 4.0 | 6.1 |

*¹The film thickness at the inner-corner portion was 700-1000 μm, and the film thickness at the planar portion was 500-800 μm.
*²In Experimental Examples 1-6, pores containing splashes with a particle size of 3 μm or less were observed.

### Evaluation

The test pieces of Experimental Examples 1-6 had a withstand voltage of 5.0 kV or more in both the inner-corner portion and the planar portion and were good products. In Experimental Examples 1-6, in both the inner-corner portion and the planar portion, the average distance between nearest pores having a pore diameter of 5.0 μm or more was 4.0 μm or more and the porosity was 8.0% or less; therefore, it was found that if this condition is satisfied, the withstand voltage becomes high. Note that characteristics of the outer-corner portion (the outer-corner curved surface covering portions 55 and 57) were equivalent to characteristics of the planar portion.

Further, the test pieces of Experimental Examples 1-4 had an even higher withstand voltage of 6.0 kV or more in both the inner-corner portion and the planar portion. In Experimental Examples 1-4, in both the inner-corner portion and the planar portion, the average distance between nearest pores having a pore diameter of 5.0 μm or more was 5.8 μm or more and the porosity was 4.0% or less. In Experimental Examples 1-4, the average pore diameter was 5.0 μm or less.

In contrast, in the test pieces of Experimental Examples 7-9, the withstand voltage of the planar portion was 5.0 kV or more, but the withstand voltage of the inner-corner portion was less than 5.0 kV. In Experimental Examples 7-9, in the inner-corner portion, the average distance between nearest pores having a pore diameter of 5.0 μm or more was less than 4.0 μm and the porosity was 8.0% or more; therefore, it is considered that the withstand voltage became low.

Note that Experimental Examples 1-6 correspond to inventive examples of the composite component of the present invention, and Experimental Examples 7-9 correspond to comparative examples. However, these inventive examples are merely preferable examples of the present invention. Therefore, the present invention is not limited in any way by the inventive examples.

This application claims priority based on Japanese Patent Application No. 2024-114829, filed on Jul. 18, 2024, and the entire contents of which is incorporated herein by reference. In addition, International Application No. PCT/JP2025/013442, filed on Apr. 2, 2025, is also incorporated herein by reference in its entirety.

What is claimed is:

1. A composite component comprising:
a conductive member having a first plane, a second plane having an angle with respect to the first plane, and an inner-corner curved surface which is a boundary surface between the first plane and the second plane; and
an insulating thermal-sprayed film that covers the first plane, the second plane, and the inner-corner curved surface;
wherein the insulating thermal-sprayed film has:
a planar covering portion that covers the first plane and/or the second plane; and
an inner-corner curved surface covering portion that covers the inner-corner curved surface;
wherein porosity of the inner-corner curved surface covering portion and porosity of the planar covering portion are 8.0% or less, and
an average distance between nearest pores having a pore diameter of 5.0 μm or more in the inner-corner curved surface covering portion and an average distance between nearest pores having a pore diameter of 5.0 μm or more in the planar covering portion are 4.0 μm or more.

2. The composite component according to claim 1,
wherein the porosity of the inner-corner curved surface covering portion and the porosity of the planar covering portion are 4.0% or less, and
the average distance between nearest pores having a pore diameter of 5.0 μm or more in the inner-corner curved surface covering portion and the average distance between nearest pores having a pore diameter of 5.0 μm or more in the planar covering portion are 5.8 μm or more.

3. The composite component according to claim 1,
wherein the porosity of the planar covering portion is smaller than the porosity of the inner-corner curved surface covering portion, and the average distance between nearest pores having a pore diameter of 5.0 μm or more in the planar covering portion is larger than the average distance between nearest pores having a pore diameter of 5.0 μm or more in the inner-corner curved surface covering portion.

4. The composite component according to claim 1,
wherein an average pore diameter of the inner-corner curved surface covering portion and an average pore diameter of the planar covering portion are 5.0 μm or less.

5. The composite component according to claim 1,
wherein the inner-corner curved surface covering portion has pores containing spherical splashes.

6. A member for a semiconductor manufacturing apparatus comprising:
a ceramic plate having a wafer placement surface on its upper surface and incorporating an electrode; and
a cooling plate having a circular upper surface to be bonded to a lower surface of the ceramic plate, a peripheral wall portion provided downward from a peripheral edge of the circular upper surface, and an annular surface provided radially outward from a lower end of the peripheral wall portion;
wherein the cooling plate is the composite component according to claim 1, the peripheral wall portion is the first plane, the annular surface is the second plane, and a boundary surface between the peripheral wall portion and the annular surface is the inner-corner curved surface.
